(19) United States
(12) Patent Application Publication
(10) Pub. No.: US 2026/0171681 A1
(43) Pub. Date: Jun. 18, 2026

(54) ANTENNA-EQUIPPED SUBSTRATE DEVICE, ARRAY ANTENNA DEVICE, AND METHOD OF MANUFACTURING ANTENNA-EQUIPPED SUBSTRATE DEVICE

(71) Applicant: Fujitsu Limited, Kawasaki-shi (JP)

(72) Inventor: Shirou OZAKI, Yamato (JP)

(73) Assignee: Fujitsu Limited, Kawasaki-shi (JP)

(21) Appl. No.: 19/413,399

(22) Filed: Dec. 9, 2025

(30) Foreign Application Priority Data
Dec. 12, 2024 (JP) 2024-217484

(51) Int. Cl. H01Q 21/06; H01Q 1/22; H01Q 9/04; H01Q 21/00; H05K 1/02; H05K 3/00

(52) U.S. Cl. CPC H01Q 21/065; H01Q 1/2283; H01Q 9/0421; H01Q 21/0087; H05K 1/024; H05K 1/0243; H05K 3/0011; H05K 2201/10098

(57) ABSTRACT

An antenna-equipped substrate device includes a wiring board having a plurality of insulating layers; an antenna having a first antenna element provided on a first surface of the wiring board; an amplifier provided on the first surface of the wiring board and connected to the first antenna element. The wiring board has a first portion where the antenna is provided and a second portion where the amplifier is provided. A thickness of the first portion of the wiring board is thinner than a thickness of the second portion of the wiring board.

### CROSS-REFERENCE TO RELATED APPLICATION

This patent application is based upon and claims the benefit of priority of the prior Japanese Patent Application No. 2024-217484 filed on Dec. 12, 2024, the entire contents of which are incorporated herein by reference.

### FIELD

The present disclosure relates to an antenna-equipped substrate device, an array antenna device, and a method of manufacturing the antenna-equipped substrate device.

### BACKGROUND

Conventionally, there is an antenna module including a substrate in which at least the uppermost surface is a single crystal of silicon carbide, a single crystal graphene layer provided in contact with the uppermost surface of the substrate, and a gallium nitride layer provided on the substrate, wherein an antenna element portion formed by patterning a region of the graphene layer not covered with the gallium nitride layer, an active element portion formed on the gallium nitride layer, and a connection portion connecting the antenna element portion and the active element portion are integrally formed (For example, see Patent Document 1.).

Patent Document 1: Japanese Unexamined Patent Application Publication No. 2023-092329

### SUMMARY

An antenna-equipped substrate device according to an embodiment of the present disclosure includes
a wiring board having a plurality of insulating layers;
an antenna having a first antenna element provided on a first surface of the wiring board;
an amplifier provided on the first surface of the wiring board and connected to the first antenna element, wherein
the wiring board has a first portion where the antenna is provided and a second portion where the amplifier is provided, and
a thickness of the first portion of the wiring board is thinner than a thickness of the second portion of the wiring board.

The object and advantages of the invention will be implemented and attained by means of the elements and combinations particularly pointed out in the appended claims.

It is to be understood that both the foregoing general description and the following detailed description are exemplary and explanatory and are not restrictive of the invention as claimed.

### BRIEF DESCRIPTION OF THE DRAWINGS

FIG. 1 illustrates an example of the configuration of an array antenna device including a plurality of antenna-equipped substrate devices of an embodiment;

FIG. 2 illustrates an example of the configuration of one antenna-equipped substrate device at a cross section taken along an arrow A-A in FIG. 1; and

FIG. 3 illustrates an example of the configuration of one antenna-equipped substrate device taken along an arrow B-B in FIG. 1.

### DESCRIPTION OF EMBODIMENTS

When an antenna and an amplifier are provided on a substrate having a plurality of insulating layers, if the thickness of the substrate is equal between a portion where the antenna is arranged and a portion where the amplifier is provided, and the thickness of the insulating layer is equal, if the frequency of a radio wave transmitted or received by the antenna increases, there is a risk that a decrease in gain may occur due to an increase in loss in the insulating layer.

Hereinafter, an embodiment to which an antenna-equipped substrate device, an array antenna device, and a method of manufacturing the antenna-equipped substrate device of the present disclosure are applied, will be described. Hereinafter, the same elements are denoted by the same reference numerals, and redundant descriptions may be omitted.

Hereinafter, the XYZ coordinate system will be defined and described. The direction parallel to the X axis (X direction), the direction parallel to the Y axis (Y direction), and the direction parallel to the Z axis (Z direction) are orthogonal to each other. The X direction is an example of a first axis direction, the Y direction is an example of a second axis direction, and the Z direction is an example of a third axis direction. For convenience of explanation, the −Z direction side may be referred to as the lower side or below, and the +Z direction side may be referred to as the upper side or above. The plane view means the XY plane view. In the following, the length, thickness, and the like of each portion may be exaggerated so as to make the configuration easier to understand. Further, the words parallel, right angle, orthogonal, horizontal, perpendicular, vertical, and the like allow a shift to a degree that does not impair the effect of the embodiment.

Hereinafter, “millimeter wave” or “millimeter wave band” includes a quasi-millimeter wave band of 24 GHz to 30 GHz in addition to a frequency band of 30 GHz to 300 GHz.

The radio waves transmitted or received by the antenna of the antenna-equipped substrate device according to the embodiment are radio waves in an ultra-high frequency band of 100 GHz or higher, assuming a sixth generation mobile communication system (6G) or the like as an example. In the ultra-high frequency band of 100 GHz or higher, it has been reported that losses in solder and wiring used for joining elements at the front end of radio wave transmission and reception of, for example, an amplifier, a phase shifter, or a mixer, adversely affect the high frequency characteristics of the module. However, the radio waves transmitted or received by the antenna of the antenna-equipped substrate device according to the embodiment may be radio waves in a millimeter wave band of a fifth generation mobile communication system (5G) or the like or in a frequency band of 1 GHz to 30 GHz including Sub-6.

Further, a case where the antenna of the antenna-equipped substrate device transmits radio waves will be described below, but because reception is the reverse operation of transmission, the antenna of the antenna-equipped substrate device can perform a reception operation in the same manner as a transmission operation.

### Embodiment

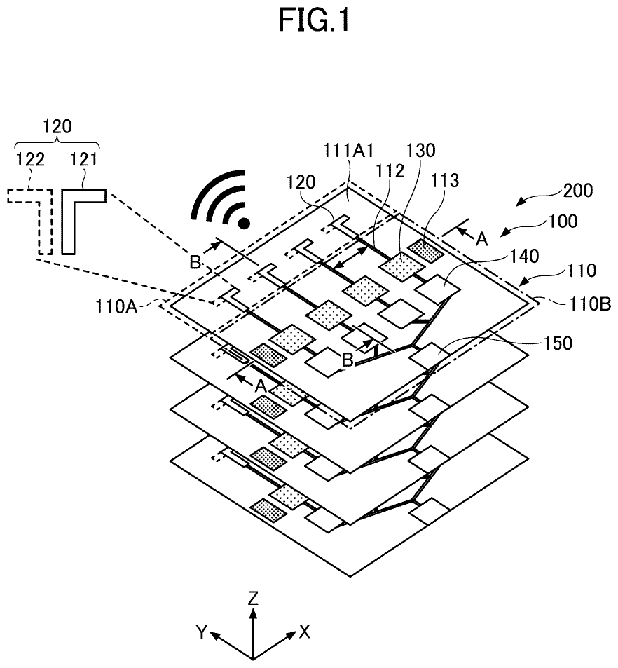

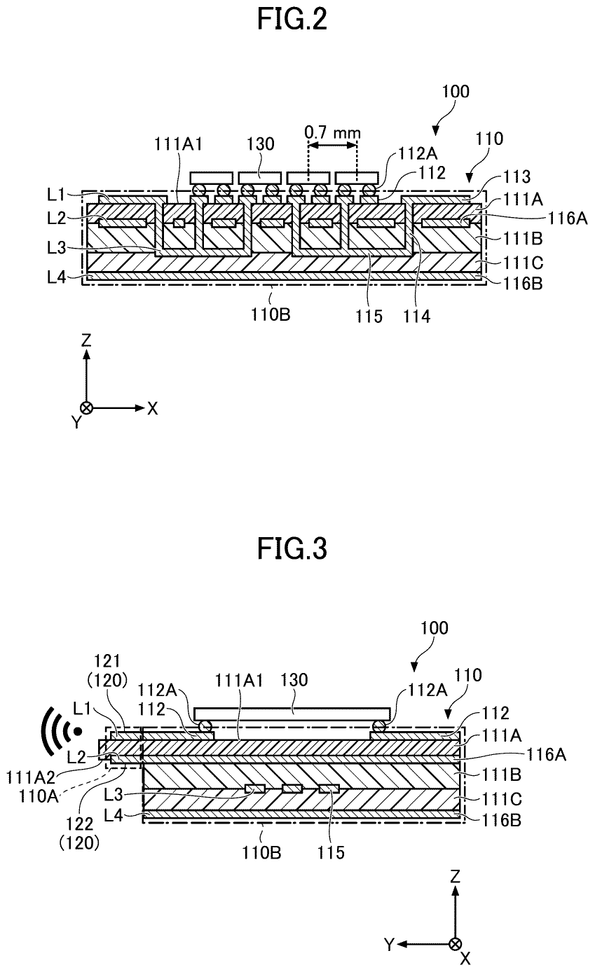

FIG. 1 is a diagram illustrating an example of a configuration of an array antenna device 200 including a plurality of antenna-equipped substrate devices 100 of the embodiment. FIG. 2 is a diagram illustrating an example of a configuration of one antenna-equipped substrate device 100 at a cross section taken along an arrow A-A in FIG. 1. FIG. 3 is a diagram illustrating an example of a configuration of one antenna-equipped substrate device 100 at a cross section taken along an arrow B-B in FIG. 1.

Hereinafter, a configuration will be described in which a radio wave transmitted or received by the antenna 120 of the antenna-equipped substrate device 100 is a radio wave of 300 GHz in an ultra-high frequency band of 100 GHz or higher assuming a sixth generation mobile communication system (6G) or the like. The wavelength of the radio wave of 300 GHz is approximately 1 mm.

### Array Antenna Device 200

The array antenna device 200 (see FIG. 1) includes a plurality of antenna-equipped substrate devices 100. FIG. 1 illustrates, as an example, the array antenna device 200 including four antenna-equipped substrate devices 100. The number of antenna-equipped substrate devices 100 included in the array antenna device 200 is not limited to four, and may be any number as long as it is at least two or more.

Here, as an example, each antenna-equipped substrate device 100 includes four antennas 120. In each antenna-equipped substrate device 100, the four antennas 120 are arranged in the X direction along a side surface extending in the X direction on the +Y direction side of the wiring board 110. Each antenna 120 of the corresponding antenna-equipped substrate device 100 can emit radio waves in the +Y direction. Each antenna-equipped substrate device 100 can change the angle of a beam with respect to the +Y direction in the XY plane by controlling the phase of radio waves transmitted by each antenna 120.

The array antenna device 200 has a configuration in which 16 antennas 120 are arrayed when the array antenna device 200 is viewed from the +Y direction side in the XZ plane view by aligning the positions of the side surfaces extending in the X direction on the +Y direction side of the wiring board 110 of each antenna-equipped substrate device 100 in a plan view and arranging the 4 antenna-equipped substrate devices 100 at equal intervals in the Z direction. The 16 antennas 120 construct a two-dimensional array antenna. The array antenna device 200 can change the angle of a beam with respect to the +Y direction in the XY plane and the YZ plane by controlling the phase of radio waves transmitted by each antenna 120 in the corresponding antenna-equipped substrate device 100. When the 4 antenna-equipped substrate devices 100 are arranged in the Z direction, the pitch of the antennas 120 adjacent to each other in the Z direction is, for example, less than 1 mm when the frequency of the radio wave transmitted by the antenna 120 is, for example, 300 GHz. That is, the pitch of the antennas 120 adjacent to each other in the Z direction is less than λ, where λ is the wavelength in the free space at the operating frequency of the antenna 120. This is to prevent grating lobes.

The array antenna device 200 is, for example, a radio communication device that can be mounted on a front end radio unit (RU) of a base station, and is mounted on a mother board or the like of the base station.

Next, the configuration of the antenna-equipped substrate device 100 will be described.

### Antenna-Equipped Substrate Device 100

The antenna-equipped substrate device 100 includes a wiring board 110, four antennas 120, four PAs (Power Amplifiers) 130, four phase shifters 140, and one mixer 150. The wiring board 110 is an example of a substrate, and the PA 130 is an example of an amplifier.

Here, the section taken along an arrow A-A in FIG. 1 and illustrated in FIG. 2 is a section taken from the end in the-X direction to the end in the +X direction of the wiring board 110, while the section taken along an arrow B-B in FIG. 1 and illustrated in FIG. 3 is a section taken from the space between the PA 130 and the phase shifter 140 of the wiring board 110 to the end in the +Y direction.

Here, a configuration in which the antenna 120 of the antenna-equipped substrate device 100 emits radio waves in the +Y direction will be described. However, the direction in which the antenna 120 of the antenna-equipped substrate device 100 emits radio waves is not limited to the +Y direction. As an example, the direction in which the antenna 120 of the antenna-equipped substrate device 100 emits radio waves may be the +Z direction.

In the case where a plurality of antennas 120 are arranged, where λ is the wavelength in the free space at the operating frequency of the antenna 120, it is common to set the pitch (distance between centers) of the adjacent antennas 120 to approximately λ/2.

However, when the operating frequency is 300 GHz, λ/2 is approximately 0.5 mm, which is an extremely narrow interval. In a configuration in which one PA 130 and one phase shifter 140 are respectively connected to each of a plurality of antennas 120 as in the antenna-equipped substrate device 100, when the pitch between the adjacent antennas 120 becomes narrow, the interval between the adjacent PAs 130 becomes narrow, and the interval between the adjacent phase shifters 140 also becomes narrow, which makes it difficult to arrange a plurality of PAs 130 and a plurality of phase shifters 140 in an integrated manner. On the other hand, when the pitch between the adjacent antennas 120 becomes too large, the radiation characteristic of the antenna 120 is degraded.

For this reason, in the antenna-equipped substrate device 100, the pitch between the adjacent antennas 120 illustrated by a double-headed arrow in FIG. 1 is preferably less than 1 mm, and is set to 0.7 mm as an example. For this reason, FIG. 2 illustrates the pitch between the adjacent antennas 120 as 0.7 mm. The pitch between the antennas 120 being less than 1 mm means that the pitch between the antennas 120 is less than the wavelength λ in the free space at the operating frequency (300 GHz) of the antenna 120. By setting the pitch between the adjacent antennas 120 to such a value, grating lobes are prevented.

### Wiring Board 110

The wiring board 110 has an insulating layer 111A, an insulating layer 111B, an insulating layer 111C, a wiring 112, a bias pad 113, a via 114, a wiring 115, a ground layer 116A, and a ground layer 116B. The insulating layer 111A is an example of a first insulating layer, and the insulating layer 111B is an example of a second insulating layer.

Here, as an example, a configuration in which the wiring board 110 has one insulating layer 111A and two insulating layers 111B will be described, but it is sufficient if the wiring board 110 has at least one insulating layer 111A and one insulating layer 111B. That is, it is sufficient if the wiring board 110 has one or more insulating layers 111A and one or more insulating layers 111B.

As an example, the wiring board 110 has a laminated structure in which three insulating layers 111A, 111B, and 111C are laminated from the +Z direction side (upper side) to the −Z direction side (lower side). On the upper surface 111A1 of the insulating layer 111A, the wiring 112 as the L1 layer, the bias pad 113, and the antenna elements 121 of the antenna 120 are located. Four antenna elements 121 of the antenna 120 are provided on the upper surface 111A1 of the insulating layer 111A. Four antenna elements 122 of the antenna 120 are provided on the lower surface 111A2 of the insulating layer 111A. The upper surface 111A1 of the insulating layer 111A is an example of the first surface of the wiring board 110. The lower surface 111A2 of the insulating layer 111A is an example of the second surface of the wiring board 110.

A ground layer 116A as an L2 layer and an antenna element 122 of an antenna 120 are positioned between the insulating layers 111A and 111B. A wiring 115 as an L3 layer is positioned between the insulating layers 111B and 111C. The wiring 115 is an interlayer wiring and is connected to the wiring 112 and the bias pad 113 via a via 114 penetrating the insulating layers 111A and 111B in the Z direction. A ground layer 116B as an L4 layer is positioned on the lower surface of the insulating layer 111C.

Further, the wiring board 110 has a first portion 110A positioned directly under a region where the four antennas 120 are positioned in plan view, and a second portion 110B other than the first portion 110A. The first portion 110A is a portion illustrated in FIGS. 1 and 3, and the second portion 110B is illustrated in FIGS. 1 to 3. While FIG. 1 illustrates the first portion 110A and the second portion 110B in plan view, the first portion 110A and the second portion 110B are three-dimensional portions having a thickness corresponding to the thickness of the wiring board 110.

The four antennas 120 are arranged in the X direction along a side surface extending in the X direction on the +Y direction side of the wiring board 110, which is rectangular in plan view. Therefore, the first portion 110A has the entire length of the wiring board 110 in the X direction, the width in the Y direction from the side surface extending in the X direction on the +Y direction side of the wiring board 110 to the boundary between the antenna element 121 and the wiring 112, and the thickness in the Z axis direction.

The second portion 110B has the entire length of the wiring board 110 in the X direction, the width in the Y direction from the boundary between the antenna element 121 and the wiring 112 to the side surface extending in the X direction on the −Y direction side of the wiring board 110, and the thickness in the Z axis direction.

As illustrated in FIG. 3, the thickness of the first portion 110A of the wiring board 110 in the Z direction is thinner than the thickness of the second portion 110B of the wiring board 110 in the Z direction. The reason why the thickness of the first portion 110A in the Z direction is thinner than the thickness of the second portion 110B in the Z direction is that the dielectric loss can be reduced by reducing the number of dielectrics located around the four antennas 120, thereby mitigating the decrease in the gain of the antennas 120.

The wiring board 110 has the insulating layer 111A, the L1 layer, and the L2 layer inside the first portion 110A, but does not have the insulating layer 111B, the insulating layer 111C, the L3 layer, or the L4 layer inside the first portion 110A. As for the via 114, a portion having a thickness of the insulating layer 111A is included in the first portion 110A.

The insulating layers 111A, 111B, and 111C can be made of, for example, one or more materials selected from polyimide, polyphenylene ether, polytetrafluoroethylene, quartz, silicon carbide, silicon nitride, silicon, and aluminum nitride.

The wiring 112 is formed on the upper surface 111A1 of the insulating layer 111A, and connects the antenna elements 121 of the four antennas 120, the four PAs 130, the four phase shifters 140, and the one mixer 150. The wiring 112 branches into four lines from the output terminal of the mixer 150, the phase shifter 140 and the PA 130 are serially inserted into each of the four wirings 112, and the end of the wiring 112 in the +Y direction is connected to the antenna element 121 of the antenna 120. The wiring 112 overlaps the ground layer 116A in plan view, and forms a microstrip line.

Two bias pads 113 are formed on the upper surface 111A1 of the insulating layer 111A. The two bias pads 113 are provided at the central portion in the Y direction, one of the two being provided at the end of the upper surface 111A1 in the −X direction and the other of the two being provided at the end of the upper surface 111A1 in the +X direction.

The bias pad 113 is connected to an external DC power supply (not illustrated), and DC power to be supplied to the PA 130 is supplied from the DC power supply. As illustrated in FIG. 2, the bias pad 113 is connected to terminals on the −X direction side of the four PAs 130 via the via 114, the wiring 115, the via 114, and the BGA (Ball Grid Array) 112A. The terminal on the +X direction side of the PA 130 in FIG. 2 is connected to the ground layer 116A via the BGA 112A, the wiring 112, and a via or the like (not illustrated).

As illustrated in FIG. 2, the four PAs 130 are arranged in the X direction with a pitch of 0.7 mm as an example. In such an arrangement, in particular, it is difficult to arrange, only by the L1, the wiring or the like for supplying DC power to the two PAs 130 located at the center among the four PAs 130. For this reason, a configuration is adopted in which power is supplied to the two PAs 130 located at the center in the X direction via the wiring 115 of the L3 layer. From the viewpoint of aligning power supply paths, power is similarly supplied to the two PAs 130 at the respective ends among the four PAs, via the wiring 115 of the L3 layer.

FIG. 2 illustrates a via 114 connecting the L1 layer and the L3 layer, and FIGS. 2 and 3 illustrate a wiring 115 located in the L3 layer and included in the power supply path to the PA 130. However, the antenna-equipped substrate device 100 includes vias and wiring other than the via 114 and the wiring 115 illustrated in FIGS. 2 and 3. Examples of such vias and wiring include vias or wiring connected to the ground layer 116A or 116B.

The ground layer 116A is located in the L2 layer and is held at a ground potential. The ground layer 116A is formed substantially over the entire portion included in the second portion 110B of the lower surface of the insulating layer 111A in plan view, and has an opening for avoiding the via 114. That is, the ground layer 116A is provided in the portion included in the second portion 110B of the L2 layer. The antenna element 122 of the antenna 120 is provided in the portion included in the first portion 110A of the L2 layer of the ground layer 116A.

The ground layer 116B is located in the L4 layer and is held at a ground potential. The ground layer 116B is formed substantially over the entire lower surface of the insulating layer 111C in plan view.

The wiring 112, the bias pad 113, the wiring 115, the ground layer 116A, and the ground layer 116B can be fabricated by patterning a metal layer such as copper. The via 114 can be fabricated by copper plating as an example.

Here, the antenna 120, the PA 130, the phase shifter 140, and the mixer 150 will be described before describing the manufacturing method of the first portion 110A and the second portion 110B.

### Antenna 120

FIG. 1 illustrates the enlarged antenna 120. The antenna 120 has two antenna elements 121 and 122. The antenna element 121 is an example of a first antenna element, and the antenna element 122 is an example of a second antenna element. The antenna element 121 is formed on the upper surface of the insulating layer 111A, and is L-shaped in plan view. The antenna element 122 is formed on the lower surface of the insulating layer 111A, and is inverted L-shaped in plan view. The antenna elements 121 and 122 are superposed so as to form a T-shape in plan view.

The antenna element 121 is connected to the PA 130 via the wiring 112 of the L1 layer, and the antenna element 122 is connected to the ground layer 116A of the L2 layer. The antenna elements 121 and 122 are electromagnetically coupled and can resonate together. The antenna elements 121 and 122 are superposed so as to form a T-shape in plan view. The antenna element 121 is supplied with an amplified signal from the PA 130 and resonates with the antenna element 122. The antenna 120 is not limited to such a configuration, as long as it can emit radio waves toward the +Y direction side.

The antenna 120 may be a Yagi-Uda antenna, a Substrate-Integrated-Waveguide (SIW) antenna, a Vivaldi antenna, a tapered slot antenna, or the like.

As an example, the antenna element 121 may be fabricated by patterning the same metal layer (as an example, copper foil) as the L1 layer. As an example, the antenna element 122 may be fabricated by patterning the same metal layer (as an example, copper foil) as the L2 layer.

An end of the antenna element 121 in the −Y direction is connected to the wiring 112 of the L1 layer, and is connected to the PA 130 via the wiring 112 and a BGA 112A as illustrated in FIG. 3.

Each antenna 120 has directivity in the +Y direction (horizontal direction as an example) and emits radio waves in the +Y direction. Because the antenna-equipped substrate device 100 includes four antennas 120 arranged along the X direction, beam forming is possible. Further, by controlling the phase of signals output to the four antennas 120 via the four PAs 130 by the four phase shifters 140, the radiation direction of the beam with respect to the +Y direction can be controlled in the XY plane.

### PA 130

The PAs 130 are mounted on the upper surface 111A1 of the insulating layer 111A of the wiring board 110. As an example, the four PAs 130 are arranged in the X direction. The PAs 130 are inserted in series between the wiring 112 connected to the antenna element 121 of the antenna 120 and the wiring 112 connected to the phase shifter 140. The reason why the PAs 130 are arranged in the front stage of the antenna element 121 of the antenna 120 is to improve the amplification efficiency of radio waves radiated from the antenna 120. Note that connecting the PAs 130 to the antenna element 121 of the antenna 120 is synonymous with connecting the PAs 130 to the antenna 120.

As illustrated in FIGS. 2 and 3, the two wirings 112 and the input and output terminals of the PA 130 are connected by the BGA 112A. That is, the PA 130 is mounted on the wiring 112 by a flip-chip mounting method. The PA 130 amplifies a signal for transmission whose phase is controlled by the phase shifter 140 and outputs the amplified signal to the antenna element 121 of the antenna 120.

As illustrated in FIG. 2, the four PAs 130 are arranged in the X direction with a pitch of 0.7 mm as an example on the upper surface 111A1 of the insulating layer 111A. That is, the pitch of the adjacent PAs 130 is equal to the pitch of the adjacent antennas 120. Although multistage amplifiers are required in order to sufficiently obtain a distance over which radio waves emitted by the antennas 120 can reach, the width of each PA 130 in the X direction is limited.

In order to implement multistage amplifiers in the PAs 130 under the condition that the arrangement in the X direction is restricted as described above, the PA 130 and the phase shifter 140 are mounted on the −Y direction side of the antenna element 121 of the antenna 120. In this configuration, because there is a relatively large margin in the Y direction, as illustrated in FIG. 3, the PA 130 is configured to be long in the Y direction to implement multistage internal amplifiers. Although FIG. 1 illustrates four PAs 130, the four PAs 130 may be integrated as one chip.

When the antenna-equipped substrate device 100 is used for reception, as an example, an LNA (Low Noise Amplifier) may be provided instead of the PA 130. In this case, different antenna-equipped substrate devices 100 are used for transmission and reception.

### Phase Shifter 140

The phase shifters 140 are mounted on the upper surface 111A1 of the insulating layer 111A of the wiring board 110. As an example, four phase shifters 140 are arranged in the X direction. The phase shifters 140 are inserted in series between the wiring 112 connected to the PA 130 and the wiring 112 connected to the mixer 150. The two wirings 112 and the input and output terminals of the phase shifter 140 are connected by a BGA in the same manner as the PA 130. The pitch between the adjacent phase shifters 140 is equal to the pitch between the adjacent antennas 120 and the pitch between the adjacent PAs 130.

The phase shifter 140 has a phase change amount controlled by a control unit (not illustrated), changes the phase of a transmission signal input from the mixer 150, and outputs the signal to the PA 130. By changing the phase of the transmission signal by the phase shifter 140, the angle of a beam emitted from the antenna-equipped substrate device 100 can be controlled.

### Mixer 150

The mixer 150 has two input terminals connected to a data output unit (not illustrated) and a local signal source, and generates a 300 GHz transmission signal by mixing an IF signal input from the data output unit with a local signal. The output terminals of the mixer 150 are connected to the input terminals of the four phase shifters 140 via wiring 112.

### Method of Manufacturing Antenna-Equipped Substrate Device 100

In a manufacturing step of the method of manufacturing the antenna-equipped substrate device 100, an etching process is performed on the wiring board 110. The etching process may be either wet etching or dry etching, but here, a manufacturing method in which wet etching is performed will be described.

First, an insulating layer 111B is attached to an insulating layer 111A, to which an L2 layer having ground layer 116A patterned thereon is attached. Next, a portion of insulating layer 111B included in first portion 110A is removed by wet etching.

Next, a metal layer for the L3 layer is attached to the surface of insulating layer 111B on the −Z direction side, and then the wiring 115 is patterned to form vias 114. Next, an insulating layer 111C is attached over the L3 layer, and a portion included in first portion 110A is removed by wet etching.

Next, the antenna element 122 of the L2 layer is patterned. Next, after a metal layer for the L1 layer is formed by plating, the antenna element 121, the wiring 112, and the bias pad 123 are patterned.

Next, the PA 130, the phase shifter 140, and the mixer 150 are mounted and singulated, thereby completing one antenna-equipped substrate device 100.

In this manner, a portion of the insulating layer 111B, the insulating layer 111C, the L3 layer, and the L4 layer located directly under the first portion 110A is removed by etching, thereby fabricating the wiring board 110 having the first portion 110A and the second portion 110B.

As an example, the insulating layer 111A is an insulating layer made of an insulating material having no photosensitivity to light radiated in a photolithography step performed by arranging a photomask on a portion included in the second portion 110B before wet etching. Such an insulating layer made of an insulating material having no photosensitivity includes, as an example, a polyimide layer having no photosensitivity (a non-photosensitive polyimide layer).

The insulating layers 111B and 111C are, as an example, insulating layers made of an insulating material having photosensitivity to light radiated in a photolithography process performed by arranging a photomask, and are constructed of, as an example, a polyimide layer having photosensitivity.

When the wiring board 110 having the insulating layer 111A constructed of a non-photosensitive polyimide layer and the insulating layers 111B and 111C constructed of a photosensitive polyimide layer is subjected to wet etching from the lower surface side, portions of the insulating layers 111B and 111C not covered with the photomask can be selectively removed.

That is, by carrying out the wet etching as described above, portions of the L1 layer, the insulating layer 111A, the L2 layer, the insulating layer 111B, the L3 layer, the insulating layer 111C, and the L4 layer of the wiring board as a base, which are located directly under the first portion 110A, can be selectively removed by the etching process. As a result, the wiring board 110 having the first portion 110A and the second portion 110B can be fabricated. The portion located directly under the first portion 110A is a portion adjacent to the insulating layers 111B and 111C of the second portion 110B on the lower surface 111A2 side of the first portion 110A, and is a portion in which the two insulating layers identical to the insulating layers 111B and 111C are removed by wet etching.

As described above, in the antenna-equipped substrate device 100, the thickness of the insulating layer 111A in the first portion 110A located directly under the region where the four antennas 120 are located in a plan view of the wiring board 110 is made thinner than the thicknesses of the insulating layers 111A to 111C in the second portion 110B other than the first portion in the wiring board 110.

Therefore, it is possible to reduce the number of dielectrics located around the four antennas 120, thereby reducing the dielectric loss and mitigating the decrease in the gain of the antennas 120.

### Effect

The antenna-equipped substrate device 100 of the present disclosure includes the wiring board 110 having a plurality of the insulating layers 111A to 111C, the antenna 120 having the antenna element 121 provided on the upper surface 111A1 of the wiring board 110, and the PA 130 provided on the upper surface 111A1 and connected to the antenna element 121, wherein the wiring board 110 has the first portion 110A provided with the antenna 120 and the second portion 110B provided with the PA 130, and the thickness of the first portion 110A of the wiring board 110 is thinner than the thickness of the second portion 110B of the wiring board 110. Therefore, it is possible to reduce the number of dielectrics located around the four antennas 120, thereby reducing the dielectric loss and mitigating the decrease in the gain of the antennas 120.

Accordingly, it is possible to provide the antenna-equipped substrate device 100 capable of mitigating the decrease in the gain of the antennas 120.

Further, the antenna 120 may be capable of radiating radio waves in a direction separated from the side surface of the wiring board 110. It is possible to provide the antenna-equipped substrate device 100 capable of radiating radio waves from the side surface of the wiring board 110 and mitigating the decrease in the gain of the antenna 120. In such an antenna-equipped substrate device 100, an array antenna device 200 having a two-dimensional array antenna can be implemented by arranging a plurality of antenna-equipped substrate devices 100 so as to line up the side surfaces thereof.

Further, the number of insulating layers in the first portion 110A of the wiring board 110 may be smaller than the number of insulating layers in the second portion 110B of the wiring board 110. By making the number of insulating layers in the first portion 110A smaller than the number of insulating layers in the second portion 110B of the wiring board 110, a configuration in which the thickness of the first portion 110A is thinner than the thickness of the second portion 110B can be easily and reliably implemented.

Further, the wiring board 110 having a plurality of insulating layers 111A to 111C is a wiring board in which one or more insulating layers 111A and one or more insulating layers 111B and 111C are laminated from the upper surface 111A1 side, and one or more insulating layers 111A are provided in the first portion 110A but a plurality of insulating layers 111B and 111C are not provided in the first portion 110A, and one or more insulating layers 111A and a plurality of insulating layers 111B and 111C may be provided in the second portion 110B. By using a wiring board 110 having a configuration in which a common insulating layer 111A is provided in the first portion 110A and the second portion 110B, and insulating layers 111B and 111C are further provided in the second portion 110B, a configuration in which the thickness of the first portion 110A is thinner than the thickness of the second portion 110B can be easily and surely implemented, and manufacturing is facilitated.

Further, on the lower surface 111A2 side of the first portion 110A opposite to the upper surface 111A1, a portion of the second portion 110B adjacent to one or more insulating layers 111B and 111C may be a portion in which one or more insulating layers identical to the one or more insulating layers 111B and 111C are removed by etching. By removing them by etching, a configuration in which the thickness of the first portion 110A is thinner than the thickness of the second portion 110B can be easily manufactured.

The etching is wet etching, the insulating layers 111B and 111C may be photosensitive insulating layers made of an insulating material that can be removed by wet etching with light irradiation, and the insulating layer 111A may be an insulating layer made of an insulating material that does not have photosensitivity. A portion of the second portion 110B adjacent to one or more insulating layers 111B and 111C can be selectively and easily removed on the side of the lower surface 111A2 opposite to the upper surface 111A1 of the first portion 110A by utilizing the difference in the properties of the materials.

Further, a plurality of antennas 120 may be included, and the plurality of antennas 120 may be arranged along the side surface. The antenna-equipped substrate device 100 that can emit beams from the side surface can be provided. Such an antenna-equipped substrate device 100 can implement an array antenna device 200 having two-dimensional array antennas that can emit beams in the direction that the side surfaces face by arranging the plurality of antenna-equipped substrate devices 100 so as to line up the side surfaces.

The array antenna device 200 of the present disclosure includes a plurality of antenna-equipped substrate devices 100, and the plurality of antenna-equipped substrate devices 100 are arranged at predetermined intervals along the direction penetrating the upper surface 111A1 while aligning the positions and directions of the side surfaces. Therefore, the number of dielectrics located around the four antennas 120 can be reduced, and the dielectric loss can be reduced, thereby mitigating the decrease in the gain of the antennas 120.

Therefore, it is possible to provide an array antenna device 200 which can mitigate the decrease in gain of the antenna 120.

Disclosed is a method for manufacturing an antenna-equipped substrate device 100, which includes a wiring board 110 having a plurality of insulating layers 111A to 111C, an antenna 120 having an antenna element 121 provided on the upper surface 111A1 of the wiring board 110, and a PA 130 provided on the upper surface 111A1 and connected to the antenna element 121, wherein the wiring board 110 has a first portion 110A on which an antenna 120 is provided and a second portion 110B on which a PA 130 is provided, wherein the portion of the first portion 110A on the side opposite to the upper surface 111A1 is removed by etching so that the thickness of the first portion 110A of the wiring board 110 is thinner than the thickness of the second portion 110B of the wiring board 110. Therefore, it is possible to reduce the amount of the dielectric material located around the four antennas 120, thereby reducing the dielectric loss and mitigating the decrease in the gain of the antennas 120.

Therefore, it is possible to provide a method of manufacturing an antenna-equipped substrate device that can mitigate the decrease in the gain of the antenna 120.

Although an antenna-equipped substrate device, an array antenna device, and a method of manufacturing an antenna-equipped substrate device according to exemplary embodiments of the present disclosure have been described above, the present disclosure is not limited to the embodiments specifically disclosed, and various modifications and changes are possible without departing from the scope of the claims.

Provided are an antenna-equipped substrate device, an array antenna device, and a method of manufacturing the antenna-equipped substrate device, which can mitigate a decrease in the gain of the antenna.

The present invention is not limited to the specific embodiments described herein, and variations and modifications may be made without departing from the scope of the present invention.

All examples and conditional language recited herein are intended for pedagogical purposes to aid the reading device in understanding the invention and the concepts contributed by the inventor to furthering the art, and are to be construed as being without limitation to such specifically recited examples and conditions, nor does the organization of such examples in the specification relate to an illustration of the superiority and inferiority of the invention. Although the embodiments of the present invention have been described in detail, it should be understood that the various changes, substitutions, and alterations could be made hereto without departing from the spirit and scope of the invention.

What is claimed is:

1. An antenna-equipped substrate device comprising:
a wiring board having a plurality of insulating layers;
an antenna having a first antenna element provided on a first surface of the wiring board;
an amplifier provided on the first surface of the wiring board and connected to the first antenna element, wherein
the wiring board has a first portion where the antenna is provided and a second portion where the amplifier is provided, and
a thickness of the first portion of the wiring board is thinner than a thickness of the second portion of the wiring board.

2. The antenna-equipped substrate device according to claim 1, wherein the antenna is configured to radiate a radio wave in a direction away from a side surface of the wiring board.

3. The antenna-equipped substrate device according to claim 1, wherein a number of the insulating layers in the first portion of the wiring board is smaller than a number of the insulating layers in the second portion of the wiring board.

4. The antenna-equipped substrate device according to claim 1, wherein
the wiring board having the plurality of insulating layers has one or more first insulating layers and one or more second insulating layers that are laminated from the first surface,
the first portion is provided with the one or more first insulating layers but is not provided with the plurality of second insulating layers, and
the second portion is provided with the one or more first insulating layers and the plurality of second insulating layers.

5. The antenna-equipped substrate device according to claim 4, wherein on a second surface opposite to the first surface, a portion of the first portion adjacent to the one or more second insulating layers of the second portion, is a portion where one or more insulating layers identical to the one or more second insulating layers have been removed by etching.

6. The antenna-equipped substrate device according to claim 5, wherein the antenna further includes a second antenna element provided on the second surface.

7. The antenna-equipped substrate device according to claim 5, wherein
the etching is wet etching,
each of the one or more second insulating layers is made of an insulating material that has photosensitivity and that can be removed by the wet etching with light irradiation, and
each of the one or more first insulating layers is made of an insulating material that does not have the photosensitivity.

8. The antenna-equipped substrate device according to claim 2, wherein
a plurality of the antennas are provided, and
the plurality of the antennas are arranged along the side surface.

9. An array antenna device comprising:
a plurality of the antenna-equipped substrate devices according to claim 2, wherein
the plurality of the antenna-equipped substrate devices are arranged at predetermined intervals along a direction penetrating the first surface, with positions and directions of the side surfaces aligned.

10. A method of manufacturing an antenna-equipped substrate device, the antenna-equipped substrate device including:
a wiring board having a plurality of insulating layers;
an antenna having a first antenna element provided on a first surface of the wiring board;
an amplifier provided on the first surface of the wiring board and connected to the first antenna element, wherein
the wiring board has a first portion where the antenna is provided and a second portion where the amplifier is provided, the method comprising:
removing, by etching, a portion of the first portion on a side opposite to the first surface, such that a thickness of the first portion of the wiring board is thinner than a thickness of the second portion of the wiring board.
